(19) United States
(12) Patent Application Publication
(10) Pub. No.: US 2019/0088808 A1
(43) Pub. Date: Mar. 21, 2019

(54) Stained Glass Cover for Photovoltaic Module

(71) Applicant: Hochschule Luzern, Horw (CH)

(72) Inventor: Stephen Wittkopf, Hergiswil (CH)

(73) Assignee: Hochschule Luzern, Horw (CH)

(21) Appl. No.: 15/998,609

(22) PCT Filed: Feb. 15, 2017
(86) PCT No.: PCT/IB2017/000114

§ 371 Date: Sep. 4, 2018

(30) Foreign Application Priority Data
Feb. 15, 2016 (DE) 10 2016 001 628.0

(51) Int. Cl. H01L 31/048

(52) U.S. Cl. CPC H01L 31/048

(57) ABSTRACT

In a cover glass for photovoltaic module (P), wherein the cover glass comprises at least one colored area (1, 2, 3, 4, 5, 6), a print opacity (D) of the colored area (1, 2, 3, 4, 5, 6) is selected such that a desired relative efficiency (RE) is achieved.

### TECHNICAL FIELD

The invention relates to a cover class according to the preamble of claim 1 as well as to a photovoltaic module, a computer-implemented data structure, a storage medium and two methods according to the coordinate claims.

### BACKGROUND ART

Photovoltaic modules are used today in many places. One possible site for photovoltaic systems are building facades, in this context also referred to as BIPV applications, with BIPV standing for “building integrated photovoltaics”.

In such BIPV applications, the objective is not necessarily that the used photovoltaic modules produce electric current as efficiently as possible. Rather, when integrating photovoltaic modules in building facades, aesthetic aspects also play a decisive role in the approval of construction projects.

In this context, among other things, there is a need for colored photovoltaic modules. Colored photovoltaic modules typically comprise a colored cover glass instead of a transparent cover glass.

The use of a colored cover glass instead of a transparent cover glass reduces the efficiency of the photovoltaic module, i.e. the relationship between the electrical energy generated by the photovoltaic module and the solar energy impinging on the photovoltaic module.

Hereinafter, the relationship between the efficiency of a photovoltaic module provided with a certain colored cover glass and the efficiency of the same photovoltaic module, when provided with a transparent cover glass, will be referred to as the photovoltaic module's relative efficiency.

One problem with such colored photovoltaic modules is that it is difficult to fabricate the colored cover glasses such that a desired relative efficiency is obtained. The inventors have found out that this is particularly problematic for multi-colored cover glasses, because differently colored areas typically lead to different relative efficiencies, which then ultimately results in the formation of so-called hot spots during operation of the photovoltaic module, i.e. areas in which significantly more solar energy hits the photovoltaic cells of the photovoltaic module than in other areas. The formation of such hot spots is very unfavorable for the operation of photovoltaic modules and in particular lead to a short-term loss of performance. In addition, the formation of hot spots can also lead to a long-term and lasting damage to the photovoltaic module.

### OBJECT OF THE INVENTION

It is the object of the invention to eliminate or to at least diminish the disadvantages of the aforementioned prior art. In particular, it is the object of the invention to find ways to safely and reliably prevent the formation of hot spots in multicolor photovoltaic modules or at least to reduce the risk of the formation of hot spots.

### SOLUTION OF THE PROBLEM

The problem is solved according to the invention by means of a cover glass for a photovoltaic module, wherein the cover glass comprises at least one colored area, wherein a print opacity of the colored area is selected such that a desired relative efficiency is achieved.

The term “print opacity” in this context should be understood as follows: The print opacity (common expression in English: print opacity) describes how large the printed portion of a total area is. In the digital printing technique used here (i.e., in the digital printing technique underlying the invention), a frequency-modulated pattern is generated, on which dots are printed. Therein, the print opacity is determined by the distance between the centers of the dots, wherein 100% is equivalent to a completely printed area with no distance between the dots. A diminishing print opacity is achieved by increasing the distance between the dots, wherein 0% means no printing. The distance between the dots is not constant everywhere, but set differently by a random generator within a certain range, i.e. the average distance is the print opacity.

Therein, it is important to realize that a fully printed surface is not automatically 100% opaque (i.e. completely non-transparent). To what extent this is the case depends on one hand on the respective primary color, because the primary colors have different densities due to their pigmentation. Another printer setting that affects the opacity of a printed area is the amount of color that is provided for a printed dot. In the printing technique underlying the invention, it is possible to use between 5 and 40 picoliter (pL) per printed dot. Only with a color quantity of 40 pL and a print opacity of 100%, a completely opaque printing is achieved. In the following, a color quantity of 10 pL is always applied as a basis, since thereby print opacities between 10% and 100% still allow enough solar energy to pass through, so that a meaningful operation of the photovoltaic module is possible.

The invention is based on the finding that for colored cover glasses for photovoltaic modules different print opacities must be used depending on the color used (and for a given color component) so that a homogeneous relative efficiency results, and that such a homogeneous efficiency is necessary for preventing the formation of hot spots.

In advantageous embodiments, the at least one colored area comprises at least one, preferably at least two, more preferably at least three of the primary colors black, white, red, green, blue and/or yellow. A particularly advantageous cover glass preferably comprises a plurality of colored areas each having at least one of the six primary colors and at most all six of the primary colors. The print opacities of all the primary colors of the cover glass are each chosen such that the desired same relative efficiency for each color is achieved, so that this particular relative efficiency arises for the cover glass as a whole.

Therein, the colored areas are at least partially angular or round, in particular triangular, quadrangular, circular, in the form of a sector of a circle and/or annular. The color quantity of a primary color preferably equals 10 pL.

Using the Natural Color System (NCS) to characterize the primary colors, the primary color black is preferably the color “NCS S 9000 N Glossy” and/or the primary color white is preferably the color “NCS S 2502 B Glossy” and/or the primary color blue is preferably the color “NCS S 4550 R80B Glossy” and/or the primary color red is preferably the color “NCS S 5040 Y80R Glossy” and/or the primary color yellow is preferably the color “NCS S 3050 Y20R Glossy” and/or the primary color green is preferably the color “NCS S 5040 G10Y Glossy”. Therein, glossy means that glossy colors and not matt ones are concerned.

However, it is not absolutely necessary that the primary colors have exactly these specifications. Rather, the invention also includes other types of white, black, blue, green, yellow and red as primary colors.

For example, the primary color “NCS S 2502 B Glossy” is a white with the nuance 2502, that is, a blackness of 25% and a chromaticness of 2%, the chromaticness being from the color blue (B). In preferred embodiments, the primary color white is a white having a blackness of 15-35% and either a chromaticness of 1-5% of the colors green (G) and/or blue (B) and/or yellow (Y) and/or red (R), or a chromaticness of 0% (N), which for example the color NCS S 3000-N contains.

The primary color “NCS S 9000 N Glossy” is a black with the nuance 9000, that is, a blackness of 90% with 0% chromaticness (N). In preferred embodiments, the primary color black is a black having a blackness of 80-10% and a chromaticness of 1-5% of the colors green (G) and/or blue (B) and/or yellow (Y) and/or red (R).

The primary color “NCS S 4550 R80B Glossy” is a blue with the Nuance 4550, that is, a blackness of 45% with 50% chromaticness, and the hue R80B, i.e. a red with 80% blue. In preferred embodiments, the primary color blue is a blue with a blackness of 35-55% and a chromaticness of 60-40%. In preferred embodiments, the hue is a hue from R70B to R90B.

The primary color “NCS S 5040 Y80R Glossy” is a red with the nuance 5040, that is, a blackness of 50% with 40% chromaticness, and the hue Y80R, that is, a yellow with 80% red. In preferred embodiments, the primary color red is a red with a blackness of 40-60% and a chromaticness of 30-50%. In preferred embodiments, the hue is a hue from Y70R to Y90R.

The primary color “NCS S 3050 Y20R Glossy” is a yellow with the nuance 3050, that is, a blackness of 30% with 50% chromaticness, and the hue Y20R, i.e. a yellow with 20% red. In preferred embodiments, the primary color yellow is a yellow with a blackness of 20-40% and a chromaticness of 40-60%. In preferred embodiments, the hue is a hue from Y10R to Y30R.

The primary color “NCS S 5040 G10Y Glossy” is a green with the nuance 5040, that is, a blackness of 50% with 40% chromaticness, and the hue G10Y, that is, a green with 10% yellow. In preferred embodiments, the primary color green is a green having a blackness of 40-60% and a chromaticness of 30-50%. In preferred embodiments, the hue is a hue from G05Y to G20Y.

The above color designations in the Natural Color System refer to colors, as they appear to a viewer when applied to a cover glass at 40 picoliters per printed dot, with a print opacity of 100%.

It is particularly advantageous if the print opacity is calculated as a function of the desired relative efficiency for the primary color blue according to the following equation:

D_{blue}=−4920+\sqrt{29284400−50000×RE}.

Therein, D_{blue} refers to the print opacity of the primary color blue and RE refers to the desired relative efficiency. Therein, the relative efficiency is between 82 and 95. Therein, D_{blue} has a tolerance of +/−10%, preferably +/−5%, more preferably +/−3%, with particular advantage +/−2%. For example, the term “tolerance of +/−10%” therein means that the print opacity D_{blue} for a relative efficiency of 90% does not necessarily have to equal exactly 57.9%, but that for D_{blue} values between 52.1% and 63.7% are actually allowed. The values for the print opacities are preferably indicated rounded to the first decimal place.

It is particularly advantageous if the print opacity is calculated as a function of the desired relative efficiency for the primary color red according to the following equation:

D_{red}133,07−\sqrt{−11594,96+294,12×RE}.

Therein, D_{red} refers to the print opacity of the primary color red and RE refers to the desired relative efficiency. Therein, the relative efficiency is between 43 and 95. Therein, D_{red} has a tolerance of +/−10%, preferably +/−5%, more preferably +/−3%, with particular advantage +/−2%.

It is particularly advantageous if the print opacity is calculated as a function of the desired relative efficiency for the primary color green according to the following equation:

D_{green}=172,23−\sqrt{−20257,54+500×RE}.

Therein, D_{green} refers to the print opacity of the primary color green and RE refers to the desired relative efficiency. Therein, the relative efficiency is between 53 and 95. Therein, D_{green} has a tolerance of +/−10%, preferably +/−5%, more preferably +/−3%, with particular advantage +/−2%.

It is particularly advantageous if the print opacity is calculated as a function of the desired relative efficiency for the primary color yellow according to the following equation:

D_{yellow}=−1074,75+\sqrt{1649907,56−5000×RE}.

Therein, D_{yellow} refers to the print opacity of the primary color yellow and RE refers to the desired relative efficiency. Therein, the relative efficiency is between 55 and 95. Therein, D_{yellow} has a tolerance of +/−10%, preferably +/−5%, more preferably +/−3%, with particular advantage +/−2%.

It is particularly advantageous if the print opacity is calculated as a function of the desired relative efficiency for the primary color black according to the following equation:

D_{black}=171,24−\sqrt{1096,8+277,78×RE}.

Therein, D_{black} refers to the print opacity of the primary color black and RE refers to the desired relative efficiency. Therein, the relative efficiency is between 17 and 95. Therein, D_{black} has a tolerance of +/−10%, preferably +/−5%, more preferably +/−3%, with particular advantage +/−2%.

It is particularly advantageous if the print opacity is calculated as a function of the desired relative efficiency for the primary color white according to the following equation:

D_{white}=−365,6+\sqrt{330439,36−2000×RE}.

Therein, D_{white} refers to the print opacity of the primary color white and RE refers to the desired relative efficiency. Therein, the relative efficiency is between 57 and 95. Therein, D_{white} has a tolerance of +/−10%, preferably +/−5%, more preferably +/−3%, with particular advantage +/−2%.

In advantageous embodiments, the cover glass comprises a mixed color, wherein the mixed color comprises at least two primary colors, wherein the mixed color is created on the cover glass by the fact that the at least two primary colors are applied in the form of a pattern onto the cover glass, wherein the respective print opacities of the primary colors are selected such that the desired relative efficiency is obtained. A mixed color produced in this way has the advantage that the impression of a homogeneous mixed color appears to a viewer of the cover glass who is far enough away, while the mixed color does not have to be produced by actually mixing the primary colors before application to the cover glass, but by applying the primary colors in a pattern. This is particularly advantageous because in this way the respective print opacities, which are necessary to produce the desired homogeneous efficiency, of all intervening primary colors can be determined in a very simple manner by means of the equations and/or tables disclosed in this application. If, on the other hand, the mixed colors were mixed with one another before application to the cover glass—so that an ink would be produced in the form of the desired mixed color—then the relationship between the print opacity and the relative efficiency would have to be determined separately for each mixed color.

In advantageous embodiments, the pattern includes stripes. Stripes are advantageous because they can be applied to the cover glass particularly easily in an even manner. In advantageous embodiments, the stripes have a width between 0.2 mm and 100 mm, preferably between 0.2 and 50 mm, particularly preferably between 0.2 mm and 1 mm. The stripes are typically arranged in parallel. Such widths offer a particularly good compromise between simple production and homogeneous mixed color impression with the viewer.

In an advantageous embodiment, the print opacity for the desired relative efficiency and the respective desired primary color is selected according to the following table:

| RE | D_{blue} | D_{white} | D_{yellow} | D_{green} | D_{red} | D_{black} |
|---|---|---|---|---|---|---|
| 60% | max (100) | 93 | 87 | 74 | 55 | 38 |
| 70% | max (100) | 71 | 65 | 51 | 38 | 28 |
| 80% | max (100) | 47 | 43 | 32 | 24 | 19 |
| 90% | 58 | 22 | 21 | 15 | 11 | 10 |

Therein, the table entry “max (100)” means that here for the primary color blue computationally a print opacity of more than 100% would be necessary to achieve the respective desired relative efficiency. It will be described further below how to typically proceed in such a case. For the print opacities given in the table for the different primary colors, in each case a tolerance of +/−10%, preferably +/−5%, particularly preferably +/−3%, with particular advantage +/−2%, applies. However, these tolerances are not noted in the table.

Selecting the print opacities for the selected primary colors according to the above table has the advantage of avoiding hot spot formation during operation of the photovoltaic module.

A photovoltaic module according to the invention comprises a cover glass according to the invention. Therein, the photovoltaic module preferably comprises a plurality of solar cells, the solar cells preferably being monocrystalline solar cells.

A computer-implemented data structure according to the invention for determining suitable print opacities for the primary colors black, white, red, green, blue and yellow, for achieving a desired relative efficiency of a cover glass for a photovoltaic module, comprises at least data of the form:

| RE | D_{blue} | D_{white} | D_{yellow} | D_{green} | D_{red} | D_{black} |
|---|---|---|---|---|---|---|
| 60% | max (100) | 93 | 87 | 74 | 55 | 38 |
| 70% | max (100) | 71 | 65 | 51 | 38 | 28 |
| 80% | max (100) | 47 | 43 | 32 | 24 | 19 |
| 90% | 58 | 22 | 21 | 15 | 11 | 10 |

Therein, the table entry “max (100)” means that here for the primary color blue computationally a print opacity of more than 100% would be necessary to achieve the respective desired relative efficiency. It will be described further below how to typically proceed in such a case. For the print opacities given in the table for the different primary colors, in each case a tolerance of +/−10%, preferably +/−5%, particularly preferably +/−3%, with particular advantage +/−2%, applies. However, these tolerances are not noted in the table.

If the covering powers for the respectively selected primary colors are selected in accordance with the above-mentioned data structure, this has the advantage that hot spot formation is avoided during operation of the photovoltaic module.

A storage medium according to the invention comprises a data structure according to the invention. The storage medium is preferably a computer-readable storage medium.

A method according to the invention for producing a cover glass according to the invention comprises the steps of:
selecting at least one color of the primary colors black, white, red, green, blue and/or yellow,
fixing a desired relative efficiency,
determining the required print opacity for each of the selected printing colors by means of at least one of the equations for determining the print opacity for the individual primary colors as a function of the desired relative efficiency,
printing the cover glass with the selected colors, wherein the printing takes place in each case with the determined print opacity.

Therein, the printing is preferably carried out by means of digital ceramic printing.

A further method according to the invention for producing a cover glass according to the invention comprises the steps of:
selecting at least one color of the primary colors black, white, red, green, blue and/or yellow,
fixing a desired relative efficiency,
determining the required print opacity for each of the selected printing colors by means of the above-mentioned table,
printing the cover glass with the selected colors, wherein the printing takes place in each case with the determined print opacity.

Therein, the printing is preferably carried out by means of digital ceramic printing.

### DESCRIPTION OF THE FIGURES

The invention is described in more detail below with the aid of diagrams and drawings, in which show:

FIG. 1: Photovoltaic module according to the invention in top view.

FIG. 2: Diagram, in which the relative efficiencies for the primary colors black, white, red, green, blue and yellow are shown as a function of the print opacity.

FIG. 3: Further embodiment of a photovoltaic module according to the invention in top view.

### DESCRIPTION OF PREFERRED EMBODIMENTS

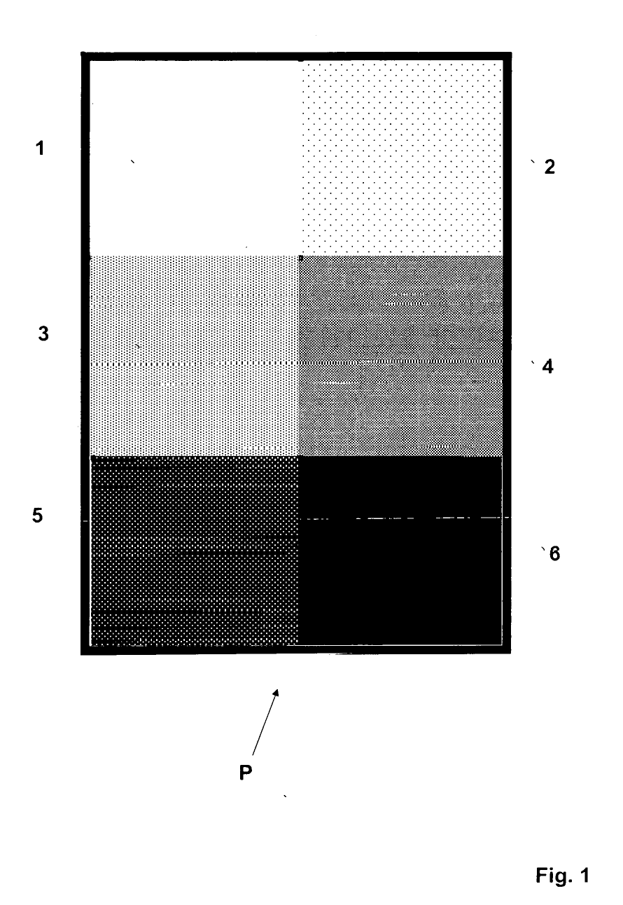

FIG. 1 shows a photovoltaic module P according to the invention in a top view. The photovoltaic module P comprises a cover glass (not provided with reference signs), which in turn comprises six colored areas, namely a white area 1, a yellow area 2, a red area 3, a green area 4, a blue area 5 and a black area 6. These six colored areas are each colored for the reason that one of the respective primary colors white, yellow, red, green, blue and black are applied there. Therein, the primary color black is the color “NCS S 9000 N Glossy”, the primary color white is the color “NCS S 2502 B Glossy”, the primary color blue is the color “NCS S 4550 R80B Glossy”, the primary color red is the color “NCS S 5040 Y80R Glossy”, the primary color yellow is the color “NCS S 3050 Y20R Glossy” and the primary color green is the color “NCS S 5040 G10Y Glossy”.

In order for the solar energy hitting the solar cells covered by the cover glass to be constant over the entire surface of the photovoltaic module P (or in other words: in order for a substantially uniform efficiency to result over the entire surface of the photovoltaic module), the respective print opacities for the individual colored areas 1, 2, 3, 4, 5 and 6 are selected unequally. In particular, the primary color white is applied onto the cover glass with a print opacity of 37%, the primary color yellow is applied onto the cover glass with a print opacity of 34%, the primary color red is applied onto the cover glass with a print opacity of 19%, the primary color green is applied onto the cover glass with a print opacity of 25%, the primary color blue is applied onto the cover glass with a print opacity of 88%, and the primary color black is applied onto the cover glass with a print opacity of 15%. This results in a substantially homogeneous relative efficiency of about 84% across the entire surface of the photovoltaic module (see the following Table 1). The mentioned print opacities were rounded to whole numbers. The mentioned print opacities for the six primary colors can be determined both by means of the above-mentioned equations and by means of the following Table 1.

TABLE 1

| RE | D_{black} | D_{white} | D_{red} | D_{green} | D_{blue} | D_{yellow} |
|---|---|---|---|---|---|---|
| 82% | 16.7 | 42.4 | 21.2 | 28.2 | 98.4 | 38.8 |
| 83% | 15.8 | 39.9 | 19.9 | 26.5 | 93.4 | 36.5 |
| 84% | 14.9 | 37.4 | 18.6 | 24.8 | 88.4 | 34.3 |
| 85% | 14.1 | 34.9 | 17.3 | 23.1 | 83.4 | 32.0 |
| 86% | 13.2 | 32.4 | 16.0 | 21.4 | 78.4 | 29.7 |
| 87% | 12.3 | 29.9 | 14.8 | 19.8 | 73.4 | 27.5 |
| 88% | 11.4 | 27.4 | 13.5 | 18.1 | 68.4 | 25.2 |
| 89% | 10.6 | 24.8 | 12.3 | 16.5 | 63.4 | 22.9 |
| 90% | 9.7 | 22.3 | 11.1 | 14.9 | 58.4 | 20.7 |
| 91% | 8.8 | 19.7 | 9.9 | 13.4 | 53.4 | 18.4 |
| 92% | 8.0 | 17.1 | 8.7 | 11.8 | 48.3 | 16.1 |
| 93% | 7.1 | 14.5 | 7.5 | 10.2 | 43.3 | 13.8 |
| 94% | 6.3 | 11.8 | 6.4 | 8.7 | 38.3 | 11.5 |
| 95% | 5.5 | 9.2 | 5.2 | 7.2 | 33.2 | 9.2 |

It is noticeable that the print opacity for the primary color blue converges faster to the maximum value of 100% than for the other primary colors and thus defines a minimum relative efficiency RE of 82% for all other primary colors. This problem can be solved by choosing a larger color quantity for the primary color blue than for the other primary colors, namely for example 20 pL instead of 10 pL. Of course, this problem only exists if the primary color blue is actually used. If the primary color blue is not used, then the minimum efficiency RE is by the respective which converges the fastest to the maximum print opacity value of 100%. If, for example, only the primary colors red and yellow are used for a specific photovoltaic module, then the primary color yellow determines a minimum relative efficiency RE of 55%, because for the primary color yellow, a relative efficiency of 55% is achieved with a print opacity value of 100% (with a color quantity of 10 pL), whereas for the primary color red, a relative efficiency of 43% is achieved with a print opacity value of 100% (with a color amount of 10 pL). These values are being obtained from the above-mentioned equations.

In another embodiment of a photovoltaic module P according to the invention, the primary color white is applied onto the cover glass with a print opacity of 71%, the primary color yellow is applied onto the cover glass with a print opacity of 65%, the primary color red is applied onto the cover glass with a print opacity of 38%, the primary color green is applied onto the cover glass with a print opacity of 51%, and the primary color black is applied onto the cover glass with a print opacity of 28%. This results in a substantially homogeneous relative efficiency of approx. 70% across the entire surface of the photovoltaic module. The mentioned print opacities for the five primary colors can be determined both by means of the above-mentioned equations and by means of the following Table 2.

The following Table 2 visualizes the values for this embodiment and also indicates three further embodiments, namely in addition to an efficiency RE of 70% for relative efficiencies RE of 60%, 80% and 90%.

TABLE 2

| RE | D_{blue} | D_{white} | D_{yellow} | D_{green} | D_{red} | D_{black} |
|---|---|---|---|---|---|---|
| 60% | max (100) | 93 | 87 | 74 | 55 | 38 |
| 70% | max (100) | 71 | 65 | 51 | 38 | 28 |
| 80% | max (100) | 47 | 43 | 32 | 24 | 19 |
| 90% | 58 | 22 | 21 | 15 | 11 | 10 |

In Table 2 it is noticeable that for the relative efficiencies 60%, 70% and 80%, the respective table entries read “max (100)” for the print opacity of the primary color blue. As already mentioned, this means that mathematically print opacities of more than 100% would be necessary here to achieve the desired relative efficiencies. If simply the maximum print opacity of 100% was used here for the primary color blue, then too much light would still penetrate the blue area, so that there would be a danger of hot spots forming here. The primary color blue is therefore not used in the photovoltaic module according to this embodiment.

However, as already described above, this problem could also be remedied by choosing a larger color quantity for the primary color blue than for the other primary colors, namely for example 20 pL instead of 10 pL.

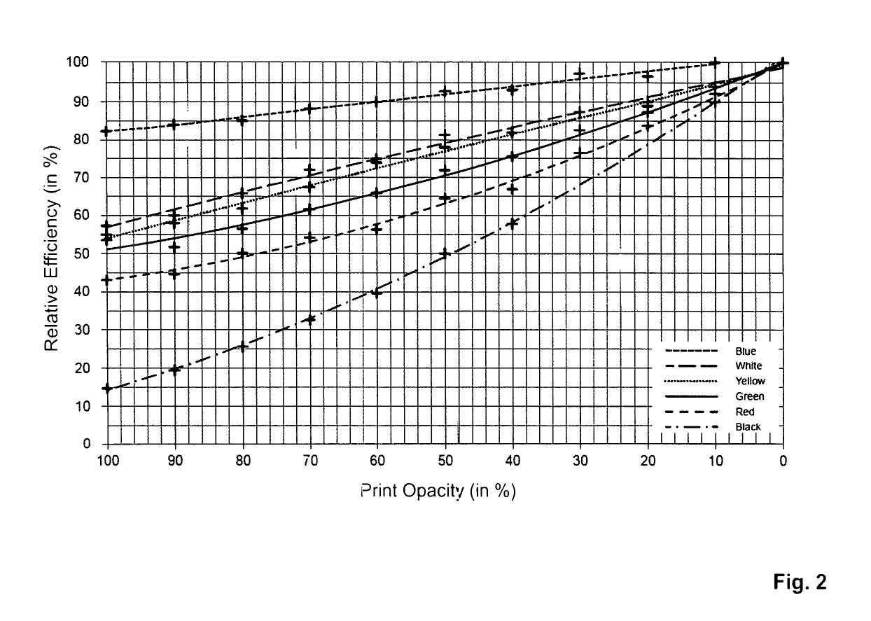

FIG. 2 shows a diagram, in which the relative efficiencies RE (wherein RE stands for “relative efficiency”; this is what the relative efficiency may also be referred to) for the primary colors blue, red, green, yellow, black and white are shown as a function of the print opacity. This diagram illustrates the surprising finding that the relative efficiencies vary more or less strongly for different primary colors at equal print opacities. The above-described “blue problem” can also be observed in FIG. 2, namely the fact that the relative efficiency RE, even with an opacity of 100%, never falls below the value of 80%. It can also be observed in FIG. 2 that comparable “limits” lie between 50% and 60% for the primary colors white, yellow and green, at approximately 40% for the primary color red and at approximately 20% for the primary color black.

To determine the equations and tables, which constitute parts of the invention, the following method was used by the inventors:

The values of the table were determined experimentally, i.e. during field trials. First, a southwest-facing PV-façade was built, containing eleven identical unshaded fields, each consisting of two standard monocrystalline PV modules. Each field was provided with a special electric power meter, which records the power produced by this field by the hour. Since for PV modules a power difference of up to +−5% is acceptable within a series, the slightly different power values of the PV fields have been normalized using a correction factor. Afterwards, glasses having the size of the PV fields were printed, namely for each of the six primary colors ten glasses with print opacities of 10, 20, 30, 40, 50, 60, 70, 80, 90 and 100%. To print the glasses, a “Glasjet Jumbo AR 6000” printer manufactured by Dip-Tech was used and printed at 10 picoliters per printed dot. This printer typically uses the colors CASS_0001 as black, CASS_0002 as white, CASS_0003 as blue, CASS_0004 as yellow, CASS_0005 as green, CASS_0006 as red, and CASS_0008 as orange, wherein CASS_0001 to CASS_0008 are the names by the manufacturer Dip-Tech. These glasses and an unprinted reference glass were mounted in front of the PV fields and their power was recorded over a time span of 3 weeks in average, wherein always at least one clear, one partly-cloudy and one overcast sky had to be present in this time span. The powers (L) of the PV fields with the printed glasses were compared with the power of the simultaneously measured reference glasses, from which the relative efficiency (RE) results as follows: RE=L (PV with printed glass)/L (PV with clear glass). This resulted in ten RE values per primary color for the ten different print opacities (only eight values were determined for the primary color black, because two cover glasses were damaged), which are summarized in Table 3 below. Subsequently, the values were translated into one equation per primary color.

TABLE 3

| D | 100 | 90 | 80 | 70 | 60 | 50 | 40 | 30 | 20 | 10 |
|---|---|---|---|---|---|---|---|---|---|---|
| blue | 82 | 84 | 85 | 88 | 90 | 92 | 93 | 97 | 96 | 100 |
| white | 57 | 60 | 66 | 72 | 75 | 81 | 82 | 86 | 90 | 94 |
| yellow | 55 | 58 | 62 | 67 | 74 | 78 | 82 | 87 | 89 | 94 |
| green | 53 | 51 | 56 | 61 | 66 | 72 | 75 | 82 | 87 | 92 |
| red | 43 | 44 | 50 | 54 | 56 | 64 | 67 | 76 | 83 | 90 |
| black | 17 | 21 | 27 | 34 | 41 | 50 | 59 | — | — | 89 |

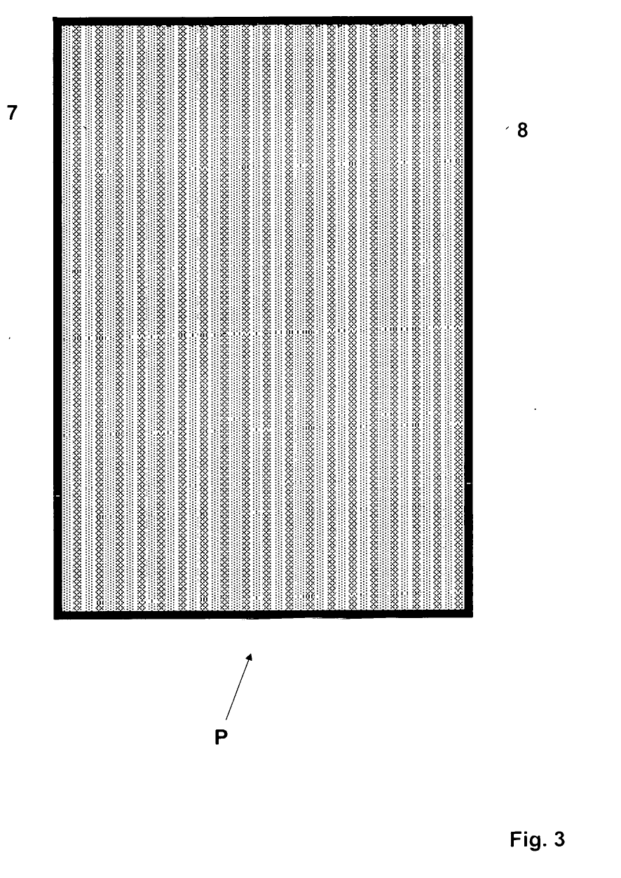

FIG. 3 shows a further embodiment of a photovoltaic module P according to the invention in top view. The photovoltaic module P comprises a cover glass (not provided with reference signs), which in turn comprises a plurality of red stripes 7 and a plurality of blue stripes 8. The red stripes 7 are red because they comprise the primary color red, and the blue stripes 8 are blue because they comprise the primary color blue. The red and blue 7, 8 are arranged in an alternating fashion and run parallel. The displayed arrangement of blue stripes 8 and red stripes 7 in a uniform pattern results in a color impression “violet” for a viewer, who is at least a few meters away from the photovoltaic module P. The print opacities of the primary colors red and blue that are used are selected such that a homogeneous desired relative efficiency RE is achieved across the entire photovoltaic module P. One possibility is that the primary color red is applied onto the cover glass with a print opacity of 19% and the primary color blue is applied onto the cover glass with a print opacity of 88%. This results in a homogeneous relative efficiency of about 84% across the entire photovoltaic module P. These numerical values are obtained from Table 1 above.

Similarly, it is possible to create the mixed color gray from the primary colors black and white. By additionally using the primary color yellow, the mixed color beige could also be produced. It is thus also possible to apply more than two primary colors in a pattern onto the cover glass. In this way, an enormous variety of mixed colors can be produced. The formation of hot spots in the photovoltaic module is thereby always avoided by determining the appropriate print opacities according to the equations and/or tables listed above.

### LIST OF REFERENCE SIGNS

1 White area
2 Yellow area
3 Red area
4 Green area
5 Blue area
6 Black area
7 Red stripe
8 Blue stripe
P Photovoltaic module

1. A cover glass for photovoltaic module, wherein the cover glass comprises at least one colored area, wherein a print opacity of the colored area is selected such that a desired relative efficiency is achieved.

2. The cover glass of claim 1, wherein the colored area comprises at least one of the primary colors black, white, red, green, blue and/or yellow.

3. The cover glass of claim 2, wherein the print opacity (D_{blue}) is calculated as a function of the desired relative efficiency (RE) for the primary color blue according to the following equation:
D_{blue}=−4920+\sqrt{29284400−50000×RE},
wherein RE is between 82 and 95 and wherein D_{blue} has a tolerance of +/−10%.

4. The cover glass of claim 2, wherein the print opacity (D_{red}) is calculated as a function of the desired relative efficiency (RE) for the primary color red according to the following equation:
D_{red}133,07−\sqrt{−11594,96+294,12×RE},
wherein RE is between 43 and 95 and wherein D_{red} has a tolerance of +/−10%.

5. The cover glass of claim 2, wherein the print opacity (D_{green}) is calculated as a function of the desired relative efficiency (RE) for the primary color green according to the following equation:
D_{green}=172,23−\sqrt{−20257,54+500×RE},
wherein RE is between 53 and 95 and wherein D_{green} has a tolerance of +/−10%.

6. The cover glass of claim 2, wherein the print opacity (D_{yellow}) is calculated as a function of the desired relative efficiency (RE) for the primary color yellow according to the following equation:
D_{yellow}=−1074,75+\sqrt{1649907,56−5000×RE},
wherein RE is between 55 and 95 and wherein D_{yellow} has a tolerance of +/−10%.

7. The cover glass of claim 2, wherein the print opacity (D_{black}) is calculated as a function of the desired relative efficiency (RE) for the primary color black according to the following equation:
D_{black}=171,24−\sqrt{1096,8+277,78×RE},
wherein RE is between 17 and 95 and wherein D_{black} has a tolerance of +/−10%.

8. The cover glass of claim 2, wherein the print opacity (D_{white}) is calculated as a function of the desired relative efficiency (RE) for the primary color white according to the following equation:
D_{white}=−365,6+\sqrt{330439,36−2000×RE},
wherein RE is between 57 and 95 and wherein D_{white} has a tolerance of +/−10%.

9. The cover glass of claim 1, wherein the cover glass comprises a mixed color, wherein the mixed color comprises at least two primary colors, wherein the mixed color is created on the cover glass by the fact that the at least two primary colors are applied in the form of a pattern onto the cover glass, wherein the respective print opacities of the primary colors are selected such that the desired relative efficiency is obtained.

10. The cover glass of claim 2, wherein the print opacity for the desired relative efficiency (RE) and the respective desired primary color is selected according to the following table:

| RE | D_{blue} | D_{white} | D_{yellow} | D_{green} | D_{red} | D_{black} |
|---|---|---|---|---|---|---|
| 60% | max (100) | 93 | 87 | 74 | 55 | 38 |
| 70% | max (100) | 71 | 65 | 51 | 38 | 28 |
| 80% | max (100) | 47 | 43 | 32 | 24 | 19 |
| 90% | 58 | 22 | 21 | 15 | 11 | 10. |

11. A photovoltaic module, comprising a cover glass of claim 1.

12. A computer-implemented data structure for determining suitable print opacities for the primary colors blue, green, red, yellow, black and white for achieving a desired relative efficiency (RE) of a photovoltaic module, comprising at least data of the form:

| RE | D_{blue} | D_{white} | D_{yellow} | D_{green} | D_{red} | D_{black} |
|---|---|---|---|---|---|---|
| 60% | max (100) | 93 | 87 | 74 | 55 | 38 |
| 70% | max (100) | 71 | 65 | 51 | 38 | 28 |
| 80% | max (100) | 47 | 43 | 32 | 24 | 19 |
| 90% | 58 | 22 | 21 | 15 | 11 | 10. |

13. A storage medium comprising a computer-implemented data structure claim 12.

14. (canceled)

15. A method for producing a cover glass claim 10, comprising the steps of:
selecting at least one color from the primary colors black, white, red, green, blue and/or yellow,
fixing a desired relative efficiency,
determining the required print opacity for each of the selected printing colors utilizing the table of claim 10, and
printing the cover glass with the selected colors,
wherein the printing takes place in each case with the determined print opacity.

16. A method for producing a cover glass claim 9, comprising the steps of:
selecting at least one color of the primary colors black, white, red, green, blue and/or yellow,
fixing a desired relative efficiency,
determining the required print opacity for each of the selected printing colors by at least one equation selected from the group consisting of:
D_{blue}=−4920+\sqrt{29284400−50000×RE},
D_{red}=133,07−\sqrt{−11594,96+294,12×RE},
D_{green}=172,23−\sqrt{−20257,54+500×RE},
D_{yellow}−−1074,75+\sqrt{1649907,56−5000×RE},
D_{black}=171,24−\sqrt{1096,8+277,78×RE}, and
D_{white}=−365,6+\sqrt{330439,36−2000×RE}, and
printing the cover glass with the selected colors, wherein the printing takes place in each case with the determined print opacity.

17. A method for determining a relative efficiency of at least one colored cover glass for a photovoltaic module, comprising the steps of:
exposing a first photovoltaic module with a transparent cover glass and a second photovoltaic module with the colored cover glass to essentially the same lighting conditions over a certain time span,
determining an average electric output power of the first photovoltaic module and an average electric output power of the second photovoltaic module, and
determining the relative efficiency by dividing the average electric output power of the second photovoltaic module by the average electric output power of the first photovoltaic module.

18. The method claim 17, wherein the determination of the relative efficiency is carried out for multiple colored cover glasses of the same color, and wherein each of the multiple cover glasses has a different print opacity.

19. The method claim 18, further comprising the step of:
deducting, from the determined relative efficiencies, at least one calculation tool selected from the group consisting of:
a table comprising, for at least one cover glass color, corresponding print opacity values for multiple relative efficiencies, and
at least one equation for calculating a print opacity value for a given cover glass color as a function of the relative efficiency.

20. The method claim 18, wherein at least one print opacity is chosen from the group consisting of 10%, 20%, 30%, 40%, 50%, 60%, 70%, 80%, 90% and 100%.

21. The method claim 17, wherein the determination of the relative efficiency is carried out for multiple printing colors, thus obtaining multiple relative efficiencies for different printing colors.
